(19) United States
(12) Patent Application Publication
(10) Pub. No.: US 2007/0216008 A1
(43) Pub. Date: Sep. 20, 2007

(54) Low profile semiconductor package-on-package

(76) Inventor: Mark A. Gerber, Lucas, TX (US)

Correspondence Address: TEXAS INSTRUMENTS INCORPORATED, P O BOX 655474, M/S 3999, DALLAS, TX, 75265, US

(21) Appl. No.: 11/384,730

(22) Filed: Mar. 20, 2006

(51) Int. Cl. H01L 23/02

(52) U.S. Cl. 257/686

(57) ABSTRACT

A semiconductor system (100) with two substrates has a first substrate (101) with a first and a second surface, electrical contact pads (110, 120) on the first and the second surface, and a central opening (130). The second substrate (102) has a third and a fourth surface, and electrical contact pads (140, 150) on the third and the fourth surface. Metal reflow bodies (160) connect the pads (120, 140) on the second and the third surface. A first semiconductor chip (103), or chip stack, is on the first surface over the opening (130), and a second semiconductor chip (104), or chip stack, is on the third surface inside the opening.

### FIELD OF THE INVENTION

The present invention is related in general to the field of semiconductor devices and processes, and more specifically to low profile, vertically integrated package-on-package semiconductor systems.

### DESCRIPTION OF THE RELATED ART

The thickness of today's semiconductor package-on-package products is the sum of the thicknesses of the semiconductor chips, electric interconnections, and encapsulations, which are used in the individual devices constituting the building-blocks of the products. This simple approach, however, is no longer acceptable for the recent applications especially for hand-held wireless equipments, since these applications place new, stringent constraints on the size and volume of semiconductor components used for these applications.

Consequently, the market place is renewing a push to shrink semiconductor devices both in two and in three dimensions, and this miniaturization effort includes packaging strategies for semiconductor devices as well as electronic systems.

Furthermore, it is hoped that a successful strategy for stacking chips and packages would shorten the time-to-market of innovative products, which utilize available chips of various capabilities (such as processors and memory chips) and would not have to wait for a redesign of chips.

### SUMMARY OF THE INVENTION

Applicants recognize the need for a fresh push to shrink semiconductor devices both in two and in three dimensions, especially for a device-stacking and package-on-package method for semiconductor devices as well as electronic systems. Furthermore, it is hoped that a successful strategy for stacking chips and packages would shorten the time-to-market of innovative products, which utilize available chips of various capabilities (such as processors and memory chips) and would not have to wait for a redesign of chips. The device can be the base for a vertically integrated semiconductor system, which may include integrated circuit chips of functional diversity. The resulting system should have excellent electrical performance, mechanical stability, and high product reliability. Further, it will be a technical advantage that the fabrication method of the system is flexible enough to be applied for different semiconductor product families and a wide spectrum of design and process variations.

One embodiment of the invention is a semiconductor system with two substrates. The first substrate has a first and a second surface, electrical contact pads on the first and the second surface, and a central opening. The second substrate has a third and a fourth surface, and electrical contact pads on the third and the fourth surface. Metal reflow bodies connect the pads on the second and the third surface. A first semiconductor chip is on the first surface over the opening, and a second semiconductor chip is on the third surface inside the opening.

The system further includes electrical connections between the first chip and the first substrate surface, and may also have encapsulation material to cover the first chip and the electrical connections between the first chip and the first substrate surface.

The system further includes electrical connections between the second chip and the third substrate surface, and may also have encapsulation material to cover the second chip and the electrical connections between the second chip and the third substrate surface so that the encapsulation material is inside the opening.

Another embodiment of the invention is a semiconductor system including two packaged semiconductor subsystems. The first packaged subsystem has a substrate with a first and a second surface, electrical contact pads on the first and second surface, and a central opening; further a first stack of semiconductor chips having bond pads, one chip of the stack attached to the first substrate surface over the opening, and one chip electrically connected to contact pads on the first substrate surface. Encapsulation material may cover the first chip stack and the electrical connections to the first substrate surface.

The second packaged subsystem has a substrate with a third and a fourth surface, and electrical contact pads on the third and the fourth surface; further a second stack of semiconductor chips having bond pads, one chip of the stack attached to the third substrate surface, and one chip electrically connected to contact pads on the third substrate surface. Encapsulation material may cover the second chip stack and the electrical connections to the third substrate surface. The second chip stack is inside the first substrate opening.

Metal reflow bodies connect the pads on the second substrate surface with the pads on the third substrate surface to couple the first and the second subsystems electrically. Metal reflow bodies are also attached to the contact pads on the fourth substrate surface to provide connections of the system to external parts.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 illustrates a schematic cross section of a system with two substrates connected by metal reflow bodies, one substrate having a central opening; one semiconductor chip is over the opening, and another semiconductor chip is inside the opening.

FIG. 2 is a schematic cross section of another system with two substrates connected by metal reflow bodies, one substrate having a central opening; one stack of semiconductor chips is over the opening, and another stack of semiconductor chip inside the opening.

FIG. 3 depicts schematic cross sections to illustrate the process of fabricating a system including two packaged subsystems, each with a substrate and a semiconductor chip stack. One substrate has a central opening to accommodate a chip stack inside.

FIG. 4 shows schematic cross sections to illustrate the process of fabricating another system including two packaged subsystems, each with a substrate and a semiconductor chip stack. One substrate has a central opening to accommodate a chip stack inside.

FIG. 5 is a schematic cross section of another system with two substrates connected by metal reflow bodies, one substrate having a central opening; one stack of semiconductor chips is over the opening, and another stack of semiconductor chip inside the opening.

### DETAILED DESCRIPTION OF THE PREFERRED EMBODIMENTS

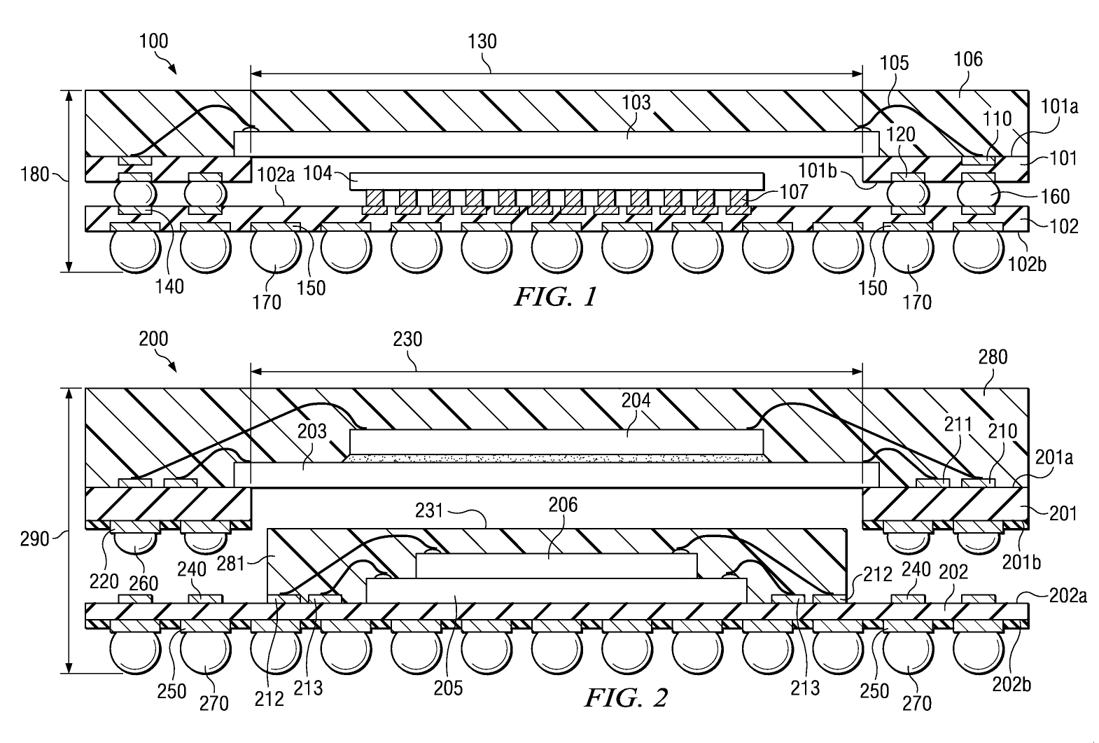

FIG. 1 is an example of an embodiment of the present invention, illustrating a vertically integrated semiconductor system with two substrates intended for connection to external parts. Due to an opening in one of the substrates for facilitating the system integration, the system has a low profile.

In FIG. 1, the system generally designated 100 has a first substrate 101 and a second substrate 102. First substrate 101 is made of an insulating body, has a first surface 101a and a second surface 101b, electrical contact pads 110 on the first surface, electrical contact pads 120 on the second surface, and a central opening of width 130. Preferred materials for substrate 101 are ceramics or polymers in a sheet-like configuration; the polymers may be stiff or compliant. The substrates have a thickness in the range from about 50 to 500 μm.

The second substrate 102 has a third surface 102a and a fourth surface 102b, electrical contact pads 140 on the third surface, and contact pads 150 on the fourth surface. Metal reflow bodies 160, such as tin or tin alloy solder members, connect pads 120 on the second surface with pads 130 on the third surface.

A first semiconductor chip 103 is on the first surface 101a over the opening 130, and a second semiconductor chip 104 is on the third surface 102a inside the opening 130. In the example of FIG. 1, chip 103 closes off opening 130. Chip 103 is preferably attached to surface 101a by an adhesive attach material such as an epoxy or a polyimide; alternatively, it may be flipped and attached by reflow or non-reflow metal studs.

The system 100 further includes electrical connections 105, such as gold wires, between the first chip 103 and the first substrate surface 101a, and may also have encapsulation material 106, such as an epoxy-based molding compound, to cover the first chip and the electrical connections between the first chip and the first substrate surface.

The system further includes electrical connections 107 between the second chip 104 and the third substrate surface 102a, and may also have encapsulation material to cover the second chip and the electrical connections between the second chip and the third substrate surface so that the encapsulation material is inside the opening. In FIG. 1, chip 104 is flipped and attached to substrate 102 by metal (preferably gold) studs 107, thus rendering an encapsulation optional.

System 100 further includes metal reflow bodies 170, preferably tin or tin alloy solder balls, attached to contact pads 150 on the fourth substrate surface 102b.

The opening 130 of first substrate 101 allows a structure of system 100 so that second chip 104 (and its encapsulation) is inside the opening. Based on this arrangement, the overall thickness 180 of system 100 is significantly less than the sum of the individual substrates and chips. As mentioned, the thicknesses of the first and the second substrate are preferably between 0.05 and 0.5 mm; the thickness of each semiconductor chip is in the 0.1 to 0.3 mm range. The total thickness 180 of system 100 depends on assembly features such as wire bonding, flip-chip assembly, encapsulation compounds, solder ball diameter, etc. With the appropriate selection of techniques, overall thickness 180 of system 100 is between about 1.0 and 1.6 mm, and is preferably about 1.4 mm.

Chip 103 and/or chip 104 may actually be stacks of two or more chips. FIG. 2 illustrates an embodiment of a semiconductor system with two substrates, wherein a stack of two chips is attached and wire bonded to the first substrate, and another stack of two chips is attached and wire bonded to the second substrate. Each chip stack is covered with encapsulation material to protect the chips and the wire bonding.

In FIG. 2, the system generally designated 200 has a first substrate 201 and a second substrate 202. First substrate 201 is made of an insulating body, has a first surface 201a and a second surface 201b, electrical contact pads 210 and 211 on the first surface, electrical contact pads 220 on the second surface, and a central opening of width 230. Preferred materials for substrate 201 are ceramics or polymers in a sheet-like configuration; the polymers may be stiff or compliant. The substrates have a thickness in the range from about 50 to 500 μm.

The second substrate 202 has a third surface 202a and a fourth surface 202b, electrical contact pads 240 on the third surface, and contact pads 250 on the fourth surface. Metal reflow bodies 260, such as tin or tin alloy solder members, connect pads 220 on the second surface with pads 230 on the third surface.

A first chip stack includes semiconductor chips 203 and 204. Chip 203 is assembled so that it is attached to first surface 201a and positioned over the opening 230; it is electrically connected (in this example, by wire bonds) to contact pads 211 on first surface 201a. Chip 204 is stacked on chip 203 using an adhesive attachment; in addition, chip 204 is electrically connected to contact pads 210 on surface 201a; in the example of FIG. 2, the connection is provided by wire bonds, alternatively, 204 could be flipped and attached by reflow members or non-reflow members. The first chip stack and the electrical connections are further packaged in encapsulation material 280, preferably an epoxy-based molding compound.

A second chip stack includes semiconductor chips 205 and 206. In the example of FIG. 2, chip 205 is adhesively attached to third surface 202a and electrically connected by wire bonds to contact pads 213 on third surface 202a. Alternatively, chip 205 may be flipped and attached and connected by bumps made of reflow (or non-reflow) metals. Chip 206 is stacked on chip 205 using an adhesive attachment (such as epoxy or polyimide). In addition, chip 206 is electrically connected to contact pads 212 (in this example, by wire bonds). The second chip stack and the electrical connections are further packaged in encapsulation material 281, preferably an epoxy-based molding compound.

System 200 includes metal reflow bodies 270, preferably tin or tin alloy solder balls, attached to contact pads 250 on the fourth substrate surface 202b.

The opening 230 of first substrate 201 allows a structure of system 200 so that the second chip stack (chips 204 and 205) and its encapsulation are inside the opening. As a consequence of the interlocking of the packaged second chip stack and opening of the first substrate, the gap 231 left between the encapsulation of the second chip stack and the passive surface of chip 203 may be vanishingly small; chip 203 and the packaged stack may actually touch. Based on this arrangement, the overall thickness 290 of system 200 is significantly less than the sum of the individual substrates and chips. As mentioned, the thicknesses of the first and the second substrate are preferably between 0.05 and 0.5 mm; the thickness of each semiconductor chip is in the 0.1 to 0.3 mm range. The total thickness 290 of system 200 depends on assembly features such as wire bonding, flip-chip assembly, encapsulation compounds, solder ball diameter, etc. With suitable selection of techniques, overall thickness 290 of system 200 is between about 1.0 and 1.6 mm, and is preferably about 1.4 mm.

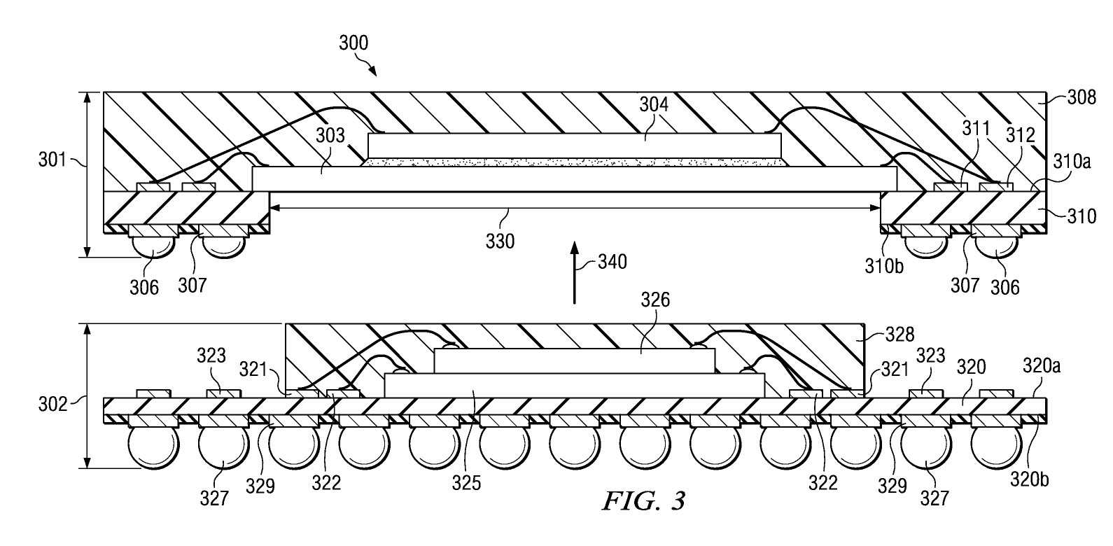

Another embodiment of the invention is a method for fabricating a semiconductor system; the method includes the steps of fabricating two packaged subsystems of specific design features, aligning the subsystems, and joining them by reflowing connection members. FIGS. 3, 4 and 7 illustrate embodiments of subsystems, and the process of joining the subsystems, and FIGS. 2, 5 and 6 depict the finished systems.

The process of fabricating the packaged first subsystem, designated 301 in FIG. 3, starts by providing a first strip 310 of an electrically insulating sheet-like body (ceramic, polymer, etc.) with a first (310a) and a second (310b) surface. Integral with the body are a plurality of electrically conducting paths (preferably copper-filled vias) from the first to the second surface, and a plurality of electrically conducting lines (preferably patterned copper layers), which extend in x-y directions of the sheet-like strip (paths and lines, and the area of the chips, are not shown in FIG. 3). Next, electrical contact pads 311 and 312 on the first and the second surface are formed; preferably, they are input/output terminals for the paths and are made of copper with a metallurgical surface amenable to wire bonding.

In the next process step, openings 330 are formed, preferably by punching or cutting; alternatively, the opening can be built up layer by layer in the substrate fabrication. It is preferred that openings 330 are approximately central relative to the locations of the contact pads 311 and 312. For many devices, opening 330 extends through the complete thickness of strip 310; for some devices, though, it may be advantageous to extend opening 330 only partially through the strip thickness. In these cases, the remaining insulator portion can be used for connecting electrical lines.

First stacks of semiconductor chips with bond pads are provided. While for some products, the stack may only contain one chip, in many products there are two or more chips in the stack; as an example, FIG. 3 shows two chips 303 and 304 in a first stack. In most embodiments, the chips are vertically aligned and attached by an adhesive layer or by flip-chip technique to form a stack.

The first stacks of semiconductor chips are assembled on the substrate by positioning one stack over each opening 330 of the strip 310. One chip (for instance, 303) is then attached to the first surface 310a using an adhesive layer. It is preferred in this attachment that the passive chip surface is facing towards the opening, since the passive surface may, in a later process step, be touched by the second packaged chip stack. The bond pads of chip 303 may then electrically be connected to contact pads 311 on the first surface 310a using wire bonding.

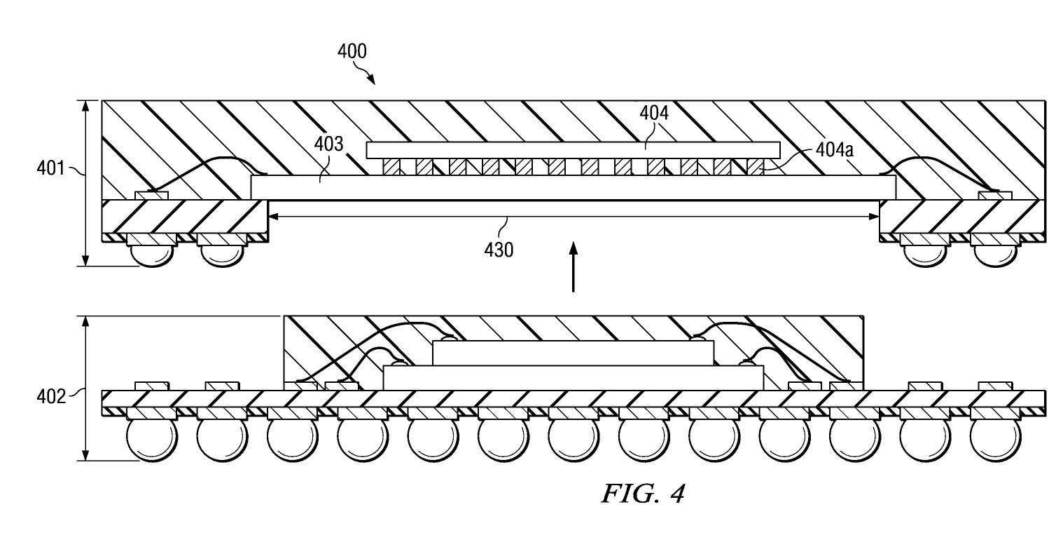

In FIG. 3, the other chip 304 of the first stack is attached to (the active surface of) chip 303 by an adhesive layer. In FIG. 4, the attachment is accomplished by a flip-chip technique so that both chips face each other with their active surfaces. In FIG. 3, bonding wires connect the bond pads of chip 304 with contact pads 312 on the first surface 310a.

In the next process step, the assembled first chip stacks and their electrical connections are encapsulated, preferably in a molding compound 308 by submitting strip 310 to a transfer molding process. Thereafter, first metal reflow bodies 306 (preferably tin or a tin alloy) are attached to the contact pads 307 on the second surface 310b. For the attachment, a first reflow temperature T₁ is used.

Strip 310 is then singulated (preferably by sawing) into individual packaged first subsystems 301. As described above, these subsystems utilize a substrate with an opening 330.

Next, the process of fabricating the packaged second subsystem, designated 302 in FIG. 3, starts by providing a second strip 320 of an electrically insulating sheet-like body (ceramic, polymer, etc.) with a third (320a) and a fourth (320b) surface. Integral with the body are a plurality of electrically conducting paths (preferably copper-filled vias) from the third to the fourth surface, and a plurality of electrically conducting lines (preferably patterned copper layers), which extend in x-y directions of the sheet-like strip (paths and lines, and the area of the chips, are not shown in FIG. 3). Next, electrical contact pads 321 and 322 on the first surface are formed, concurrently with contact pads 323; further, contact pads 307 on the second surface are formed. Preferably, these contact pads are input/output terminals for the paths and are made of copper with a metallurgical surface amenable to wire bonding and solder attachment.

Next, second stacks of semiconductor chips with bond pads are provided. While for some products, the stack may only contain one chip, in many products there are two or more chips in the stack; as an example, FIG. 3 shows two chips 325 and 326 in a second stack. In most embodiments, the chips are vertically aligned and attached by an adhesive layer or by flip-chip technique to form a stack.

The second stacks of semiconductor chips are assembled on the substrate strip 320. One chip (for instance, 325) is attached to the first surface 320a using an adhesive layer. The bond pads of chip 3225 may then electrically be connected to contact pads 322 on the first surface 320a using wire bonding.

In FIG. 3, the other chip 326 of the second stack is attached to (the active surface of) chip 325 by an adhesive layer. Bonding wires connect the bond pads of chip 326 with contact pads 321 on the first surface 320a.

In the next process step, the assembled second chip stacks and their electrical connections are encapsulated, preferably in a molding compound 328 by submitting strip 320 to a transfer molding process. Compound 328 is selected to withstand the reflow temperature of metal reflow bodies 327. Thereafter, second metal reflow bodies 327 (preferably a high-melting tin alloy) are attached to the contact pads 329 on the fourth surface 320b. For the attachment, a second reflow temperature T₂ is used, which is selected so that T₂ is higher than the first reflow temperature T₁ employed for attaching first metal reflow bodies 306.

Strip 320 is then singulated (preferably by sawing) into individual packaged second subsystems 302.

The manufacturing method continues by selecting a first subsystem 301 and a second subsystem 302. In the next process step, subsystem 301 and subsystem 302 are aligned so that first metal reflow bodies 306 contact the contact pads 323 on the third surface, and the second chip stack is placed inside the first substrate opening 330. This movement step is indicated in FIG. 3 by arrow 340.

Thermal energy is then applied to raise the temperature of the aligned system to T₁, causing the first reflow bodies 306 to melt and connect to contact pads 323. After cooling to ambient temperature, the selected subsystems 301 and 302 are connected to a unified system 200 as described in FIG. 2.

FIG. 4 illustrates the manufacturing process of a system where one of the subsystems (401) has a stack of chips assembled by flip-chip technology. Substrate 410 of subsystem 401 has an opening of width 430. The chip stack of this example includes chips 403 and 404. Chip 403 is assembled on substrate 410 so that it is positioned over the opening 430 and connected by wires bonding to contact pads of substrate 401. Chip 404 is stacked on chip 403 in flip-chip fashion using connecting bumps 404a; for tight bump pitch, the preferred method employs gold studs 404a. Subsystem 402 has a chip stack packaged in an encapsulation and sized so that, during assembly, the chip stack can be at least partially inserted in opening 430 of substrate 410.

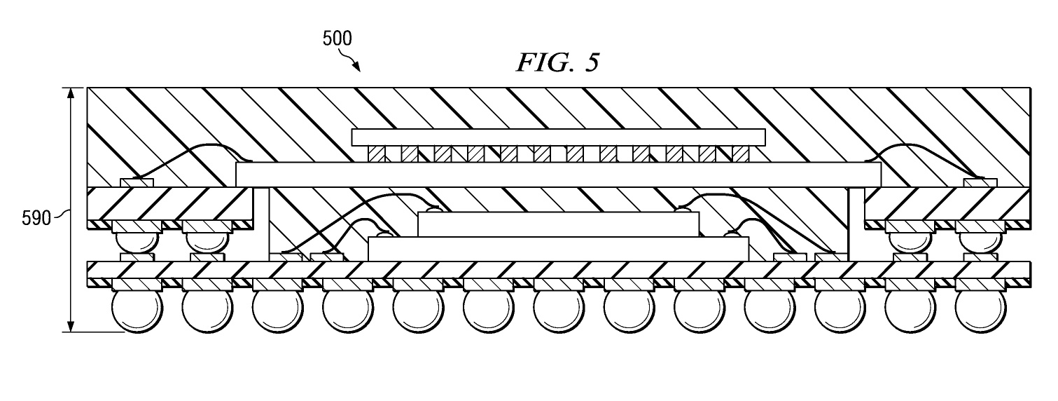

FIG. 5 depicts the fully assembled system 500. Based on the interlocking of the two subsystems, the overall thickness 590 is significantly less than 2 mm; thickness 590 is in the range of about 1.0 to 1.6 mm, preferably about 1.3 mm. When the second chip stack in subsystem 402 also employs flip-chip technology for stacking its chips, the overall thickness of a system like system 500 may be about 1.2 mm.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of semiconductor chip, discrete or integrated circuit, and the material of the semiconductor chip may comprise silicon, silicon germanium, gallium arsenide, or any other semiconductor or compound material used in integrated circuit manufacturing.

As another example, the process step of encapsulating can be omitted when the integration of the system has been achieved by flip-chip assembly.

It is therefore intended that the appended claims encompass any such modifications or embodiment.

I claim:

1. A semiconductor system comprising:
a first substrate having a first and a second surface, electrical contact pads on the first and the second surface, and a central opening;
a second substrate having a third and a fourth surface, and electrical contact pads on the third and the fourth surface;
metal reflow bodies connecting the pads on the second and the third surface;
a first semiconductor chip on the first surface over the opening; and
a second semiconductor chip on the third surface inside the opening.

2. The system according to claim 1 further including electrical connections between the first chip and the first substrate surface.

3. The system according to claim 2 further including encapsulation material covering the first chip and the electrical connections between the first chip and the first substrate surface.

4. The system according to claim 1 further including electrical connections between the second chip and the third substrate surface.

5. The system according to claim 4 further including encapsulation material covering the second chip and the electrical connections between the second chip and the third substrate surface so that the encapsulation material is inside the opening.

6. The system according to claim 1 further comprising a third chip having bond pads, the third chip stacked with the first chip so that one chip of the stack is attached to the first substrate surface over the opening, and one chip electrically connected to contact pads on the first substrate surface.

7. The system according to claim 1 further comprising a fourth chip with bond pads, the fourth chip stacked with the second chip so that one chip of the stack is attached to the third substrate surface, and one chip electrically connected to contact pads on the third substrate surface.

8. The system according to claim 1 further including metal reflow bodies attached to the contact pads on the fourth substrate surface.

9. A method for fabricating a system comprising the steps of:
fabricating a packaged first subsystem including the steps of:
providing a first strip of an electrically insulating sheet-like body with a first and a second surface;
forming electrical contact pads on the first and the second surface;
forming openings in the body, centrally positioned relative to the contact pads;
providing first stacks of semiconductor chips having bond pads;
assembling the stacks by positioning one stack over each opening, attaching one chip to the first surface, and connecting one chip electrically to contact pads on the first surface;
attaching first metal reflow bodies to the contact pads on the second surface using a first reflow temperature; and
singulating the strip into individual packaged first subsystems having a first substrate with an opening;
fabricating a packaged second subsystem including the steps of:
providing a second strip of an electrically insulating sheet-like body with a third and a fourth surface;
forming electrical contact pads on the third and the fourth surface;
providing second stacks of semiconductor chips having bond pads;
assembling each stack by attaching one chip of each stack to the third surface, and connecting one chip electrically to contact pads on the third surface;
attaching second metal reflow bodies to the contact pads on the fourth surface using a second reflow temperature higher than the first reflow temperature; and
singulating the strip into individual packaged second subsystems;
selecting a first subsystem and a second subsystem;
aligning and contacting the first metal reflow bodies with the contact pads on the third surface, and placing the second chip stack inside the first substrate opening; and
reflowing the first reflow bodies using the first reflow temperature, thereby connecting the selected first and the second subsystems.

10. The system according to claim 9 further including the step of covering the assembled first chip stacks with first encapsulation material, before the step of attaching the first metal reflow bodies.

11. The system according to claim 9 further including the step of covering the assembled second chip stacks with second encapsulation material, before the step of attaching the second metal reflow bodies.
